(19) United States
(12) Patent Application Publication
(10) Pub. No.: US 2012/0167980 A1
(43) Pub. Date: Jul. 5, 2012

(54) SOLAR CELL

(75) Inventor: Peter Engelhart, Leipzig (DE)

(73) Assignee: Q-CELLS SE, Bitterfeld-Wolfen / OT Thalheim (DE)

(21) Appl. No.: 13/395,081

(22) PCT Filed: Jun. 25, 2010
(86) PCT No.: PCT/EP10/59093

§ 371 Date: Mar. 8, 2012

(30) Foreign Application Priority Data
Sep. 10, 2009 (DE) 10 2099 043 975.7

(51) Int. Cl. H01L 31/0216; H01L 31/04

(52) U.S. Cl. 136/256; 136/252

(57) ABSTRACT

The invention relates to a solar cell with a semiconductor wafer comprising a light incidence facing front side with a base electrode, which is connected to a base layer of the semiconductor wafer, and a front side opposite to the back side with an emitter electrode, which is connected to an emitter structure of the semiconductor wafer, characterized by that the emitter structure comprises a front side emitter layer arranged on the front side of the semiconductor wafer.

The invention relates to a solar cell with both-sided contacting.

In a wafer based solar cell made of a semiconductor wafer, for example out of silicon, the semiconductor wafer material acts as an absorber material, to absorb light impinging on a light incidence facing front side and convert it to electrical energy. When the semiconductor wafer comprises surfaces that are well enough electrically passivated, the absorber material contributes significantly to the recombination losses in the solar cell and limits therefore the energy conversion efficiency.

At present, the market for wafer based silicon solar cells is dominated by both-sided contacted solar cells, which have a p-type base layer and an n-type emitter structure. The p-type base layer is typically produced by boron doping of the semiconductor wafer, while thereon the n-type emitter structure is routinely formed by way of phosphor doping. While the emitter structure and the emitter electrodes connected thereto are arranged on the front side, base electrodes are arranged on a back side of the semiconductor wafer opposite the front side.

Described simply, in a semiconductor, electrons can be trapped easier by defects in the semiconductor material, than holes. This is associated, among other factors, with the higher mobility of electrons in comparison to holes. On the other hand, the physical properties of a doped semiconductor are determined primarily by minority carriers in the semiconductor. Therefore, p-type semiconductors with electrons as minority carriers generally show a higher recombination activity in comparison to n-type semiconductors having the same level of impurity or density of recombination centers. This behavior can be described physically by the so called Shockley-Read-Hall formalism and is know in the literature. Furthermore, silicon wafers produced by the Czochralski process and subsequently formed into p-type semiconductors by way of boron doping, show a further negative effect under light exposure, which is known by the term Boron-Oxygen degradation. Due to this degradation, which sets in and advances in time, the recombination rate of charge carriers in the semiconductor increases, so that a solar cell produced out of it experiences a drop in its efficiency.

Semiconductors designed as n-type do not have these disadvantages and have therefore significantly higher efficiencies. High efficiency solar cells based on an n-type base layer made of n-type wafers (bulk material), are designed in the industrial production either as back side contacted solar cells (back-junction solar cells), or as solar cells having hetero-contacts. Due to their technologically complicated design, the technological hurdle for the introduction of solar cells having n-type base layers is therefore very high.

In EP 1 732 142 A1, a wafer based solar cell is disclosed, which has a phosphor doped base layer. On the front side of the n-type semiconductor wafer, base electrodes are arranged, which are connected to the base layer through a base contact layer. On the back side of the semiconductor wafer, an emitter layer and thereon an emitter electrode are placed, covering the whole area. While this arrangement is technologically simpler than the two previously described solar cell designs, it has the disadvantage that the current collection probability is very low, because charge carriers produced by way of the incident light on the front side of the semiconductor wafer will first have to pass the relatively thick base layer to be collected by the emitter layer placed on the back side.

It is therefore the object of the invention to provide for a solar cell that is built technologically simple and at the same time has a high efficiency.

The object is solved according to the invention by a solar cell with the features of claim 1. Advantageous embodiments of the invention are subject of the sub-claims.

The invention is based on the idea to provide a both-sided contacted solar cell with front side placed base electrodes and back side placed emitter electrodes with an emitter structure, which comprises a front side emitter layer placed on the front side of the semiconductor wafer. Due to the front side emitter layer being placed on the front side, the charge carrier pairs produced by light incidence on the front side of the semiconductor wafer are separated by way of a junction between the emitter structure and the base layer, and conducted away as electric current through the base and emitter electrodes. The charge carriers then don't have to pass through the base layer anymore, before being collected by a back side emitter layer. Therefore, the probability that they recombine in the base layer decreases, leading to a rise of the solar cell efficiency.

The front side emitter layer can hereby comprise one continuous or multiple, from each other separated sections on the front side. These sections may for example be separated due to base electrodes placed in-between them. In order to connect the front side emitter layer of the emitter structure with the emitter electrode on the back side of the semiconductor wafer, through holes may be provided in the semiconductor wafer, the walls of which are metalized or which are completely filled with an electrically conducting material. Such a structure is known by the expression metal wrap through (MWT).

The emitter electrode and/or the base electrode may be produced by way of applying a metal paste, in particular a silver containing paste for the base electrode, and a following heating process (firing process) for forming semiconductor-electrode contacts. Herein, by way of a single heating process, both the emitter electrode and also the base electrode may be produced from the applied metal pastes. The metal pastes may be applied by way of screen printing, by way of inc-jet printing, or by way of another suitable process. Due to the both-sided contacting of the solar cell, conventional interconnection techniques and devices may be utilized for interconnecting multiple solar cells to a solar cell module. In particular, the solar cells may continue to be interconnected to solar cell strings by way of cell connectors.

In an advantageous embodiment, it is provided that the emitter structure comprises a back side emitter layer arranged on the back side of the semiconductor wafer, and a transfer region, which extends over a wafer edge region and/or along wall regions of a through hole formed in the semiconductor wafer to the front side of the semiconductor wafer. The back side emitter layer, the transfer region, and the front side emitter layer are connected together or merge into each other and therefore form a so-called emitter-warp-through (EWT) structure, if the transfer region extends along the wall regions of the through holes, or an emitter-wrap-around (EWA) structure, if the transfer region extends over the wafer edge region.

In a preferred embodiment, it is provided that the emitter structure extends at least over about 92% of the front side of the semiconductor wafer, preferably over at least about 95%. In other words, the front side emitter layer extends over at least 92% or 95% of the semiconductor wafer front side. Herein, the front side emitter layer may itself be covered by one or multiple layers, for example by an antireflective layer.

In an advantageous embodiment, it is provided that the base electrode is connected to the base layer through a base contact structure, whereby the base contact structure comprises spaced apart base contact regions and/or a front side base contact layer. The spaced apart base contact regions are preferably finger-shaped and may border on each other underneath a base busbar, or they may be connected to each other electrically via a base busbar.

When providing a front side base contact layer, multiple base electrodes on the semiconductor wafer front side may be connected to the base layer via a common front side base contact layer. Such a front side base contact layer, which advantageously extends over substantially the entire front side of the semiconductor wafer, has the advantage that it increases the lateral conductance of the solar cell for the charge carriers collected from the base layer. These charge carriers may also flow first along the shortest path through the base layer to the front side base contact layer, and from there with a lower electric resistance to the individual base electrodes.

On the other hand, base contact regions spaced apart from each other have the advantage, that the semiconductor wafer front side usually has a higher current collection probability, since there is no base contact region in the surface region between the base electrodes. In order to minimize the recombination losses of the semiconductor front side, the front side base contact layer may be formed very thin along a substantial portion of the front side of the semiconductor wafer, while in an immediate vicinity of the base electrodes and/or immediately below the base electrodes, it is thicker. Herein, by “thicker” are meant both an embodiment, wherein the corresponding regions or layers have a physically larger vertical extension, as well as an embodiment, wherein the doping density at the corresponding regions or layers is increased.

In principle, recombination losses immediately underneath of metallic base electrodes are minimized by increasing the doping density, or thickening the base contact region or the front side base contact layer there. In contrast, recombination losses at the surface regions, where there is no metallization, for example in regions between finger-shaped base electrodes, are minimized by that there the base contact regions or the front side base contact layer are less pronounced or even not existing.

The base contact regions may be finger-shaped and may comprise base contact regions underneath of busbars. Alternatively, the solar cell may be formed without busbars, such that the finger-shaped base contact regions do not border on each other any place on the front side on the semiconductor. The base contact regions may, on the other hand, in an advantageous embodiment, be formed point-shaped, whereby such base contact points have to provide a suitable minimum surface for the subsequent contacting. The base contact points are preferably arranged in a grid pattern. The point-shaped base contact regions are base contact regions that are not only spaced apart from each other, but that are also separated from each other, in the sense that they are not electrically connected to each other through further base contact regions, but only via the base layer or additionally via base electrodes or via interconnection elements for interconnecting of solar cells into modules. This applies also for the previously described finger-shaped base contact regions in solar cells without base busbars.

Preferably, it is provided that the front side emitter layer is arranged between the base layer and the front side base contact layer. For this, for example first the emitter structure may be produced on the entire semiconductor wafer, for example by way of thermal diffusion. Subsequently, emitter layer openings are produced in the front side emitter layer, through which a contacting between the base layer and the base contact structure is to be carried out. Afterwards, the front side base contact layer is produced on the front side of the semiconductor wafer.

In an advantageous embodiment, it is provided that the front side base contact layer is arranged between the front side emitter layer and the base layer. Therefore, herein, the front side base contact layer and the front side emitter layer are arranged on the base layer in a reversed order compared to the previously described embodiment. This has the advantage that an electric connection of lower resistivity can be formed between the base layer and the base electrodes.

In a preferred embodiment, it is provided that the base contact structure comprises a back side base contact layer arranged between the back side emitter layer and the base layer. In this case, the back side base contact layer does not serve for electrically connecting the base layer with the base electrodes. Instead, it may serve to influence the transfer region between the base layer and the back side emitter layer in its physical properties.

A substantial advantage of the back side base contact layer is, similar to the case of the front side base contact layer or the front side base contact regions, that it increases the lateral conductance of the base layer. The majority carriers (electrons in the case of a back side base contact layer of n⁺-type) can move naturally in the back side base contact layer, in order to be re-emitted into the base layer directly underneath of the front side base contact regions or base electrode regions. Afterwards, the majority carriers have only to pass the relatively thin (for example 100-200 μm), high resistance base layer and reach the front side base contact region or base electrode. Therefore, the back side base contact layer, like the front side base contact layer, forms an equipotential surface.

In an advantageous embodiment, it is provided that the base layer, the base contact structure and/or the emitter structure comprise at least in sections a surface passivation. The surface passivation is preferably designed as a surface passivation layer, which may be formed in sections on the base layer, the front side base contact layer, the front side emitter layer and/or the back side emitter layer. It may be a chemical and/or preferably a field effect passivation.

In all herein described embodiments, further layers may be provided, in order to influence the optical and/or electrical properties of the solar cell. Examples of them encompass front side antireflective layers and back side reflection layers. Furthermore, the front side of the semiconductor wafer is preferably provided with a texturing, in order to capture a larger portion of the incident light and therefore increase the total efficiency of the solar cell.

In a preferred embodiment, it is provided that the surface passivation comprises aluminum oxide (Al2O3). Such a surface passivation is preferably applied by way of atomic layer deposition (ALD). In this manner, a very effective passivation may be achieved, whose thickness is very precisely adjustable. Alternatively, also other materials and methods may be utilized for forming a surface passivation, for example SiN_{X} or deposited or thermally grown silicon oxide.

In an advantageous embodiment, it is provided that the base layer comprises an n-type semiconductor and the emitter structure comprises a p-type semiconductor. In embodiments with a base contact structure, the same is preferably formed of an n⁺-type semiconductor. Preferably, it is provided that the base contact structure is made by phosphor doping and the emitter structure is made by boron doping of the semiconductor wafer.

In an advantageous embodiment, it is provided that the emitter electrode is formed as a full area back side metallization, which covers the back side of the semiconductor wafer substantially completely. The emitter electrode may be produced by way of a whole surface application of an aluminum paste onto the semiconductor wafer back side and a subsequent heat treatment step. Preferably, however, it is produced by way of a deposition process, for example by way of physical vapor deposition (PVD), whereby also here the metallization is formed preferably with aluminum.

In a preferred embodiment, it is provided that the base layer, the emitter structure and/or the base contact structure are formed in the semiconductor wafer by doping. Herein, parts of these structures, individual structures or even all three structures may be produced by way of doping the semiconductor wafer, without utilizing additional deposition methods. The deposition and/or application methods may then be utilized in forming the electrodes and further layers.

In the following, exemplary embodiments of the invention are described with reference to the accompanying drawings. Herein, with schematic cross-section views:

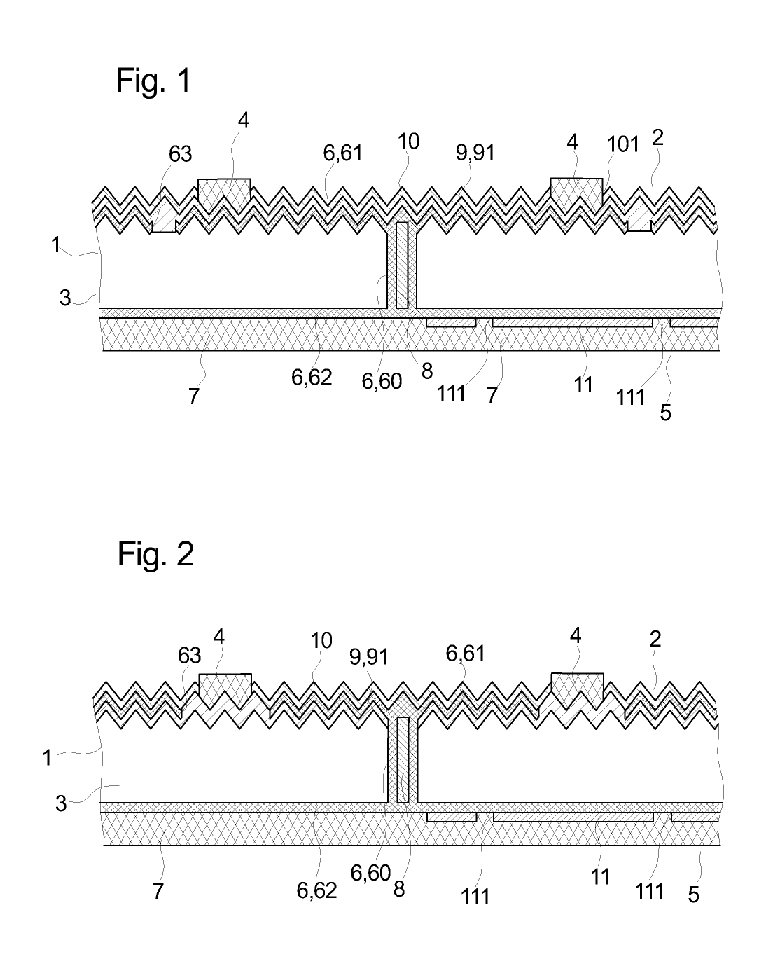

FIG. 1 shows a solar cell having a front side base contact layer and a front side emitter layer;

FIG. 2 shows a solar cell having a front side base contact layer and a front side emitter layer according to a further embodiment;

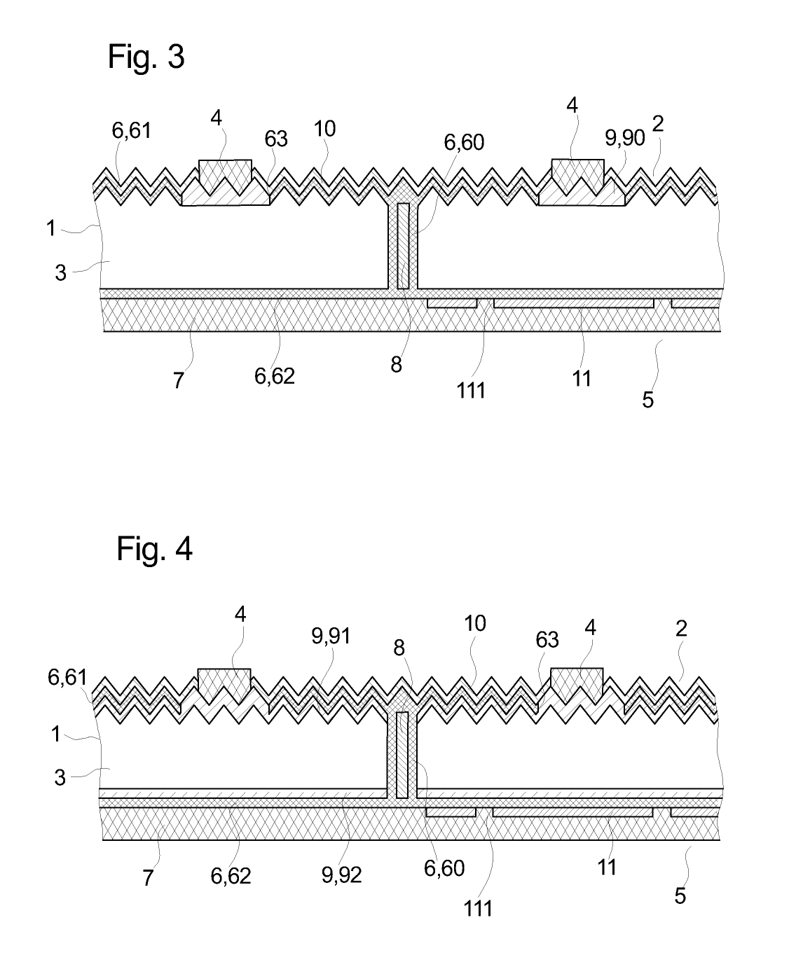

FIG. 3 shows a solar cell having spaced apart base contact regions on the front side of the semiconductor wafer; and

FIG. 4 shows a solar cell having a front side and a back side base contact layer.

The FIG. 1 shows a solar cell having a semiconductor wafer 1 comprising a base layer 3. Advantageously, the base layer 3 has emerged out of a semiconductor wafer 1, by making it into an n-type semiconductor by way of phosphor doping. The semiconductor wafer 1 may for example be from a silicon wafer, which has emerged from a Czochralski process. The front side 2 of the semiconductor wafer 1 is textured, in order to increase the light capturing probability and thus the efficiency of the solar cell. The Texturing is illustrated schematically by way of a “zig-zag” patterned surface in the FIGS. 1 to 4.

On the base layer 3 of the semiconductor wafer 1, an emitter structure 6 is formed, comprising a front side emitter layer 61, a back side emitter layer 62, and a transfer region 60. In the herein described embodiment having for example a phosphor doped n-type base layer 3, the emitter structure 6 is formed as p-type, preferably by way of boron doping.

The transfer region 60 extends along wall regions of a through hole 8, which is formed into the semiconductor wafer 1, for example by way of laser-assisted drilling. The solar cell in the embodiment according to FIG. 1 is therefore formed as an EWT solar cell (EWT—emitter wrap through). This is also the case in the further embodiments, which are shown in FIGS. 2 to 4. In alternative embodiments, however, the through hole 8 may only be completely or in part metalized, which is the case in an MWT solar cell (MWT—metal wrap through).

On the front side 2 of the semiconductor wafer 1, a front side base contact layer 91 is formed on the entire surface of the front side emitter layer 61 as part of a base contact structure 9 and connected to the base layer 3 through emitter layer openings 63 in the front side emitter layer 61. On the front side base contact layer 91, base electrodes 4 are arranged, which are electrically connected to the base layer 3 via the base contact structure 9. In the herein described embodiments having an n-type base layer 3, the base contact structure 9 is formed out of an n⁺-type semiconductor material, for example once more by way of phosphor doping.

Finally, the front side 2 of the semiconductor wafer 1 is covered by a surface passivation layer 10, whereby the base electrodes 4 are exposed for contacting purposes. Instead or in addition to the surface passivation layer 10, also an antireflective layer may be provided on the front side 2. The surface passivation 10 may for example be made of SiN_{X} or aluminum oxide (Al₂O₃).

On a back side 5 of the semiconductor wafer 1 opposite to the front side 2, a whole-surface emitter electrode 7, which comprises aluminum, is placed on the back side emitter layer 62. The emitter electrode 7 may have been produced for example by way of applying a metal paste, for example aluminum paste by way of screen printing, and a subsequent heat treatment. Advantageously, however, the emitter electrode 7 is formed by way of physical vapor deposition (PVD), if necessary combination with further metallization processes for reinforcing the thus formed metallization layer and/or for enhancing its solderability.

In between the emitter electrode 7 and the back side emitter layer 62, a dielectric layer 11 is positioned on a section of the back side 5, having layer openings 111, through which a contacting of the emitter electrode 7 with the back side emitter layer 62 occurs. The dielectric layer 11 is in all the herein shown embodiments only optional and may for example serve for surface passivation. For this reason, it is preferably made of aluminum oxide and preferably by way of atomic layer deposition (ALD method).

The FIG. 2 shows a further embodiment of the solar cell, which differs from the embodiment of FIG. 1 by that on the front side 2 of the semiconductor wafer 1, the order of the front side emitter layer 61 and a front side base contact layer 91 has been changed. In other words, the front side base contact layer 91 is positioned between the base layer 3 and the front side emitter layer 61 and contacted with the base electrodes 4 through emitter layer openings 63 in the front side emitter layer 61. The photovoltaically active zone of the front side 2 of the semiconductor wafer 1 is therefore formed by a junction between the emitter structure 6 and the base contact structure 9.

A further embodiment of a solar cell is shown in FIG. 3. The same reference numerals are used for the same structural elements, and in order to avoid reputation, it is explicitly referred to the previous descriptions. Unlike in the embodiments shown in FIG. 1 and FIG. 2, the base contact structure 9 shown here comprises, instead of the front side base contact layer 91, multiple base contact regions 90 directly underneath the base electrodes 4.

Finally, a further embodiment of the solar cell is shown in the FIG. 4, wherein the base contact structure 9, besides the front side base contact layer 91, which in the embodiment according to FIG. 2 is formed between the base layer 3 and the front side emitter layer 61, comprises a back side base contact layer 92. The back side base contact layer 92 is herein not provided for connecting the base layer 3 with the base electrodes 4. Rather, it serves for increasing the lateral conductivity of the majority carriers of the base layer. Furthermore, it can serve to influence the physical properties of a junction between the base layer 3 and the emitter structure 6 on the back side 5 of the semiconductor wafer 1. In the herein described n-type base layer 3, the bank side base contact layer 92 is preferably formed like the front side base contact layer 91 as n⁺-type.

### REFERENCE NUMERALS

1 semiconductor wafer
2 front side of the semiconductor wafer
3 base layer
4 base electrode
5 back side of the semiconductor wafer
6 emitter structure
60 transfer region
61 front side emitter layer
62 back side emitter layer
63 emitter layer opening
7 emitter electrode
8 through hole
9 base contact structure
90 base contact region
91 front side base contact layer
92 back side base contact layer
10 surface passivation, surface passivation layer
11 dielectric layer
111 layer openings

1. A solar cell with a semiconductor wafer comprising:
a light incidence facing front side with a base electrode, which is connected to a base layer of the semiconductor wafer, and
a back side opposite to the front side, the back side having an emitter electrode, which is connected to an emitter structure of the semiconductor wafer, the emitter structure comprising a front side emitter layer arranged on the front side of the semiconductor wafer.

2. The solar cell according to claim 1, wherein the emitter structure comprises
a back side emitter layer arranged on the back side of the semiconductor wafer, and
a transfer region, which extends over at least one of a wafer edge region and along wall regions of a through hole formed in the semiconductor wafer to the front side of the semiconductor wafer.

3. The solar cell according to claim 1, wherein the emitter structure extends at least over about 92% of the front side of the semiconductor wafer.

4. The solar cell according to claim 1, wherein the base electrode is connected to the base layer through a base contact structure, whereby the base contact structure comprises at least one of spaced apart base contact regions and a front side base contact layer.

5. The solar cell according to claim 4, wherein the front side emitter layer is arranged between the base layer and the front side base contact layer.

6. The solar cell according to claim 4, wherein the front side base contact layer is arranged between the front side emitter layer and the base layer.

7. The solar cell according to claim 4, wherein the base contact structure comprises a back side base contact layer arranged between the back side emitter layer and the base layer.

8. The solar cell according to claim 1, wherein at least one of the base layer, the base contact structure and the emitter structure comprise at least in sections a surface passivation.

9. The solar cell according to claim 8, wherein the surface passivation comprises aluminum oxide (Al2O3).

10. The solar cell according to claim 1, wherein the base layer comprises an n-type semiconductor and the emitter structure comprises a p-type semiconductor.

11. The solar cell according to claim 8, wherein the base contact structure is made by phosphor doping and the emitter structure is made by boron doping of the semiconductor wafer.

12. The solar cell according to claim 1, wherein the emitter electrode is formed as a full area back side metallization, which covers the back side of the semiconductor wafer substantially completely.

13. The solar cell according to claim 1, wherein at least one of the base layer, the emitter structure and the base contact structure are formed in the semiconductor wafer by doping.

14. A solar cell according to claim 2, wherein the emitter structure extends at least over about 92% of the front side of the semiconductor wafer.

15. A solar cell according to claim 2, wherein the base electrode is connected to the base layer through a base contact structure, whereby the base contact structure comprises at least one of spaced apart base contact regions and a front side base contact layer.

16. The solar cell according to claim 3, wherein the base electrode is connected to the base layer through a base contact structure, whereby the base contact structure comprises at least one of spaced apart base contact regions and a front side base contact layer.

17. The solar cell according to claim 5, wherein the base contact structure comprises a back side base contact layer arranged between the back side emitter layer and the base layer.

18. The solar cell according to claim 6, wherein the base contact structure comprises a back side base contact layer arranged between the back side emitter layer and the base layer.

19. The solar cell according to claim 1, wherein the emitter structure extends at least over about 95% of the front side of the semiconductor wafer.

20. A solar cell according to claim 2, wherein the emitter structure extends at least over about 95% of the front side of the semiconductor wafer.
